(19) United States
(12) Patent Application Publication
(10) Pub. No.: US 2026/0050055 A1
(43) Pub. Date: Feb. 19, 2026

(54) Generalized multi-kernel GRAPPA approach for high-fidelity EPI reconstruction

(71) Applicant: The Board of Trustees of the Leland Stanford Junior University, Stanford, CA (US)

(72) Inventors: Nan Wang, Redwood City, CA (US); Daniel Raz Abraham, Palo Alto, CA (US); Kawin Setsompop, Stanford, CA (US); Adam Bruce Kerr, Menlo Park, CA (US); Hua Wu, San Jose, CA (US)

(21) Appl. No.: 19/298,812

(22) Filed: Aug. 13, 2025

Related U.S. Application Data
(60) Provisional application No. 63/682,430, filed on Aug. 13, 2024.

(51) Int. Cl. G01R 33/561; G01R 33/48; G01R 33/56

(52) U.S. Cl. CPC G01R 33/5616; G01R 33/482; G01R 33/5608; G01R 33/5611

(57) ABSTRACT

A method for magnetic resonance imaging (MRI) includes: performing with an MRI scanner, an MRI data acquisition to acquire MRI data including calibration data for kernel training and regular EPI data in single polarity; performing preprocessing of the MRI data including performing readout interpolation to Cartesian grids and first-order gradient delay correction; performing a generalized multi-kernel GRAPPA using network-based kernels trained from the calibration data to correct spatial-varying field imperfections; applying the network-based kernels to the regular EPI data to obtain clean data; and reconstructing corrected single-polarity EPI data to obtain clean images using a parallel imaging reconstruction algorithm.

### CROSS-REFERENCE TO RELATED APPLICATIONS

This application claims priority from U.S. Provisional Patent Application 63/682,430 filed Aug. 13, 2024, which is incorporated herein by reference.

### STATEMENT OF FEDERALLY SPONSORED RESEARCH

This invention was made with Government support under contract EB019437, EB033206, and MH116173 awarded by the National Institutes of Health. The Government has certain rights in the invention.

### FIELD OF THE INVENTION

The present invention relates generally to magnetic resonance imaging (MRI). More specifically, it relates to methods for correcting imperfections in MRI.

### BACKGROUND OF THE INVENTION

In the performance of magnetic resonance imaging (MRI), the hardware system imperfections including gradient errors and field perturbation (such as eddy current), which can induce severe image artifacts and degrade the clinical and scientific outcomes, have been a long-standing challenge. Particularly, echo planar imaging (EPI), an efficient sampling strategy with fast-switching dual polarity gradients, is largely subject to such system imperfections because the switching gradient polarity induces opposite imperfections on odd and even echoes. The associated artifacts on EPI images become more prominent for advanced imaging practice, including higher acquisition acceleration, stronger gradient and slew rate, and higher field strengths. This vastly limits the ability of EPI to further improve image performance and speed.

### SUMMARY OF THE INVENTION

In one aspect of the invention, a generalized multi-kernel GRAPPA technique is provided, which utilizes machine learning to correct the spatial-varying field imperfection on EPI data for the production of artifact-free clean images without increasing the scan time. The technique can be used for EPI acquisition on different systems, different field strengths, and different sampling designs.

This technique benefits not only EPI but also numerous other MRI applications troubled by system imperfections. For example, multi-echo gradient echo (GRE) is also troubled by the field-imperfection-induced artifacts. To mitigate such artifacts, multi-echo GRE, in challenging cases, uses monopolar readout instead of bipolar readout, which reduces artifacts but, in the meantime, significantly decreases its sampling efficiency.

Compared to existing techniques, generalized multi-kernel GRAPPA utilizes machine learning to represent spatial-varying field imperfections for a spatial-varying correction. In addition to regular data acquisition, generalized multi-kernel GRAPPA includes the acquisition of one set of field-imperfection-corrupted calibration data and the corresponding clean calibration data at the beginning of each imaging session to train kernels. The trained kernels are used to correct the following field-imperfection-corrupted data in the same imaging session. This technique is easy to apply to different EPI experiments and does not affect acquisition time and the sampling efficiency of the following acquisitions.

In contrast with the present invention, Dual Polarity GRAPPA (DPG) is a Siemens product software to correct the field imperfection. It also acquires a pair of corrupted and clean calibration data to provide a kernel for data correction. However, it only provides a single kernel over different kₓ-k_{y} locations, which is not capable of correcting spatial varying field perturbations. Nowadays, the pursuit of faster EPI sampling and higher spatial resolution has facilitated the use of larger portion of ramp sampling, higher undersampling rate, and more powerful gradient systems with higher maximum gradient and slew rate. These aspects have exaggerated the eddy current effect, leading to stronger spatial variation of field imperfection. In these applications, DPG has not been able to provide clean images.

Dual polarity averaging (DPA) is another widely used method. It acquires every image in dual polarities and averages them for ghost-free images. DPA shows improvement in image quality over DPG in the above-mentioned challenging applications. However, DPA doubles the acquisition time of each image, resulting in reduced efficiency.

The generalized multi-kernel GRAPPA technique is provided to resolve the spatial varying field perturbations in EPI. One approach was developed to use multi pairs of kernels to represent the varying phase errors along the readout. This approach is referred to as multi-kernel dual-polarity GRAPPA (multi-kernel DPG). In this approach, the calibration data with similar kₓ locations are grouped to train a kernel that can map the single-polarity corrupted data to the dual-polarity-averaged clean data. Multiple kernels along kₓ dimension are obtained. After the training, the kernels are applied to the acquired single-polarity corrupted data at the corresponding kₓ-k_{y} locations to produce clean data that can be used for the reconstruction of clean images. This multi-kernel DGP approach accommodates the spatial-varying system imperfections along the kₓ dimension.

A challenge for multi-kernel DPG is that the amount of training data for each kernel decreases with the increase in the number of kernels. When the spatial variation of phase is rapid and more pairs of kernels are required, the noise level for each kernel is amplified. The correlation along the multiple pairs of kernels is not appreciated in multi-kernel DPG.

A more advanced approach was developed, which uses neural network-based kernels to exploit the correlation of the spatial-varying field imperfections and provide a compact representation of the imperfections. This approach is referred to as field correcting GRAPPA (FCG). For the demonstration, we used a Multi-layer Perceptron (MLP) network to serve as the kernel in FCG. The input for MLP kernel training is data points of three adjacent spatial locations along the kₓ dimension from single-polarity field-imperfection-corrupted calibration data. The paired output is the center data point from the corresponding spatial locations from clean calibration data. By including the training pairs from different k-space locations, the MLP kernel can capture the spatial-varying information between the corrupted data and the clean data. After the training, the MLP kernel can be used to correct the field-imperfection-corrupted data in the same imaging session.

We demonstrate obtaining the pair of the corrupted data and the artifact-free clean data. The clean data can be acquired in many approaches. Two approaches are illustrated. Approach (1) is to acquire the corrupted data twice, once with positive readout polarity, and once with negative readout polarity. The average of the dual polarity data cancels out a large portion of the field imperfection and produces nearly clean data. Approach (2) is to directly estimate the field imperfection using a field camera during the acquisition of the single-polarity calibration data and include such information in the reconstruction to produce clean images.

A reconstruction pipeline was developed to achieve artifact-free images. One way to reconstruct the clean image is to perform the correction directly on the acquired single-polarity system-imperfection-corrupted data as a separate upfront correction step. In this approach, at the beginning of the imaging session, the corrupted calibration data and the paired clean calibration data through approaches described above are acquired as the training data to obtain the kernel(s). Following this, regular acquisition of single-polarity corrupted data is performed. The trained kernel(s) is (are) applied to the corrupted data. Subsequently, the image reconstruction can be performed on the corrected data for artifact-free clean outcomes. However, this is not the only approach. The reconstruction of the clean image can also be performed with parallel imaging by including the imperfections in the forward model.

Pipelines for calibration data acquisition and image reconstruction were also developed for simultaneous multi-slice (SMS) EPI. SMS-EPI is widely applied clinically and scientifically due to its ability to accelerate EPI acquisitions. It is also strongly challenged by spatial varying field perturbations. To applied the generalized multi-kernel GRAPPA approaches on SMS EPI, the dual-polarity calibration data is acquired in slice-by-slice manner. The calibration data was directly slice-collapsed to form the synthetic corrupted SMS data. To form the synthetic clean SMS data, the calibration data of each slice was corrected with linear ghost correction, averaged over dual polarities, and slice-collapsed. The kernel(s) is(are) trained to map the synthetic corrupted SMS data to the synthetic clean SMS data. Afterwards, the trained kernel(s) can be applied to correct single-polarity SMS-EPI data in the acquisition. After data correction, any proper image reconstruction method can be used to reconstruct the clean SMS-EPI data, including SENSE, slice-GRAPPA, etc.

The present generalized multi-kernel GRAPPA technique can improve the correction of multi-echo GRE and enables the bipolar readout to increase efficiency even in challenging cases. Echo-planar time-resolved imaging (EPTI), an advanced distortion-free ultrafast quantitative imaging technique based on EPI, will benefit from the correction approach of this invention as well. In those techniques, the FCG can be performed in the same way.

MRI companies could use these techniques to correct field-imperfection (gradient error, eddy current, etc.) related artifacts and produce significantly improved image quality for all EPI-based techniques across the whole body. This technology is particularly important for emerging MRI techniques with higher acceleration and finer resolution, and for emerging MRI systems with powerful gradient systems and higher field strength.

In one aspect, the invention provides a method for magnetic resonance imaging (MRI) comprising: performing with an MRI scanner, an MRI data acquisition to acquire MRI data including calibration data for kernel training and regular EPI data having single polarity; performing preprocessing of the MRI data including performing readout interpolation to Cartesian grids and first-order gradient delay correction; performing a generalized multi-kernel GRAPPA using network-based kernels trained from the calibration data to correct spatial-varying field imperfections; applying the network-based kernels to the regular EPI data to obtain clean data; and reconstructing corrected single-polarity EPI data from the clean data using a parallel imaging reconstruction algorithm.

The method may also include generating clean reference data from an average of the calibration data. The method may also include training the network-based kernels to map single-polarity corrupted data to dual-polarity averaged clean data. The method may also include applying the network-based kernels to acquired single-polarity corrupted data to produce clean data, and using the clean data for reconstruction of clean images. The method may also include training a multi-layer perceptron-based kernel to map adjacent k-space points in single-polarity corrupted calibration data to a center data point of corresponding spatial locations from dual-polarity-averaged clean calibration data.

### BRIEF DESCRIPTION OF THE DRAWINGS

FIG. 1A Is a graph in k-space of an EPI trajectory with R=4 design and 4 shot, full-ramp sampling.

FIG. 1B are graphs of Skope measurement error between targeted and the actual field vs time.

FIG. 1C is a schematic diagram illustrating dual polarity average (DPA) sampling.

FIG. 1D is a schematic diagram illustrating dual-polarity GRAPPA (DPG) and multi-kernel DPG, according to an embodiment of the invention.

FIG. 1E is a schematic diagram illustrating FCG with MLP kernel, according to an embodiment of the invention.

FIG. 2 is an image grid showing phantom results with ramp sampling EPI trajectory as in FIG. 1A.

FIG. 3 is an image grid showing in vivo results from a Magnus system.

FIG. 4 is an image grid showing in vivo SMS-EPI results from a Magnus system.

FIG. 5A is a flow chart outlining steps of a standard EPI online reconstruction.

FIG. 5B is a flow chart outlining steps of a generalized multi-kernel GRAPPA in an EPI scan, according to an embodiment of the present invention.

### DETAILED DESCRIPTION OF THE INVENTION

### Introduction

Echo planar imaging (EPI) is a rapid imaging method that has been extensively used in numerous MRI applications, such as diffusion imaging, perfusion imaging, and functional MRI (fMRI). To achieve rapid k-space sampling, EPI employs fast gradient switching between positive and negative polarity readouts during data acquisition. Such dual-polarity sampling is subject to field perturbations from gradient errors and system interaction (e.g., eddy-current). The field perturbations often induce differences between the opposing polarity readout gradient sampling grids, manifesting as Nyquist ghosts in the image domain. Most Nyquist ghost correction (NGC) algorithms model the difference between positive and negative readout k-space lines as a first-order (linear plus scalar) phase correction offset along the frequency encoding (x) direction in hybrid (x-k_{y}) space. However, the combined impact of eddy currents, magnetic susceptibility effects, and local spatial sensitivity of multichannel detectors can potentially introduce higher-order effects. The artifacts associated with residual higher-order phase differences between odd-even echoes can significantly degrade image quality, especially for high-resolution imaging with more undersampling, a stronger gradient system, or higher field strength.

Over years, tremendous efforts have been made to address the higher-order odd-even artifacts. Field probe based measurements can be used to improved image quality, but relies on an additional external device. Dual-Polarity-GRAPPA (DPG) showed promising correction in EPI with limited ramp-sampling but produced a higher error when adopted to cases with large ramp sampling due to changing field across k-x. Dual polarity average (DPA), which directly acquires two datasets with opposite readout polarity sequentially and complex-averaged them, demonstrated encouraging results but led to twice the scan time.

To address the problem, we developed generalized multi-kernel GRAPPA technique. Two feasible approaches are demonstrated: (1) multi-kernel DPG, and (2) Field-Correcting GRAPPA (FCG). Both approaches are kernel-based approaches. Multi-kernel DPG trains multiple kernels along kₓ to compensate for the spatial varying phase errors. FCG trains a network-based kernel to provide a compact representation of the spatiotemporal varying imperfections along kₓ and thus achieves high-quality correction. The generalized multi-kernel GRAPPA technique has demonstrated feasibility in the field correction for ultrafast EPI trajectories with different acceleration setups (including in-plane acceleration as well as simultaneous multi-slice [SMS] acquisition) at various field strengths (3T and 7T). It is a promising technique to unleash the speed of EPI for future ultrafast MRI applications.

### Methods

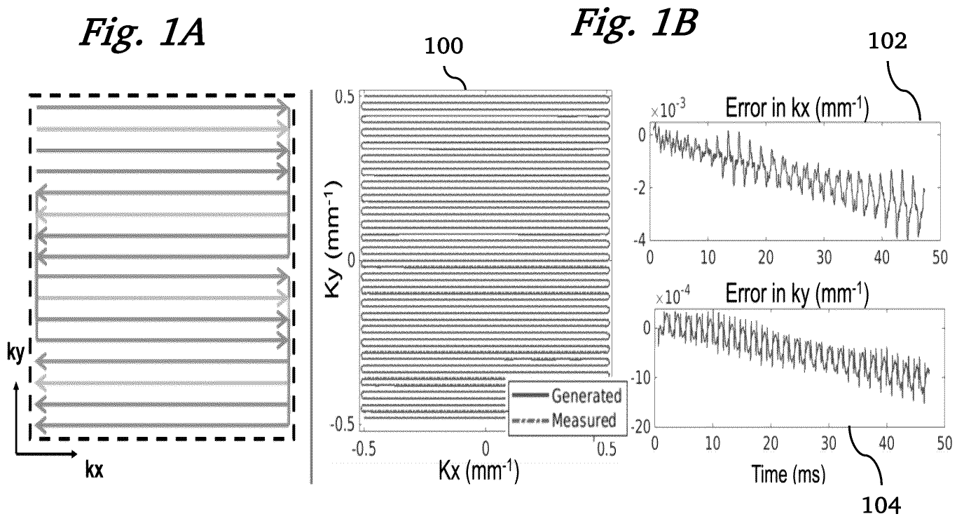

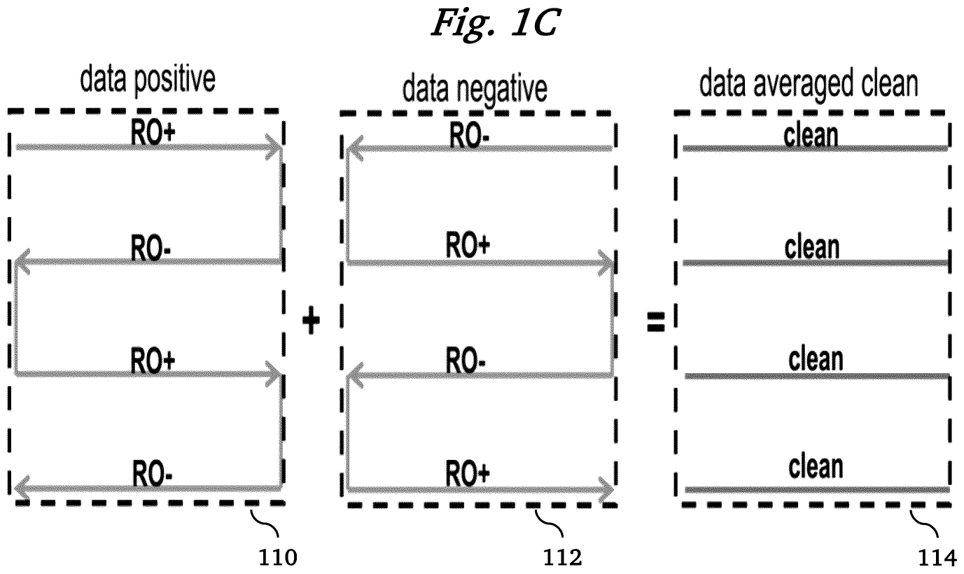

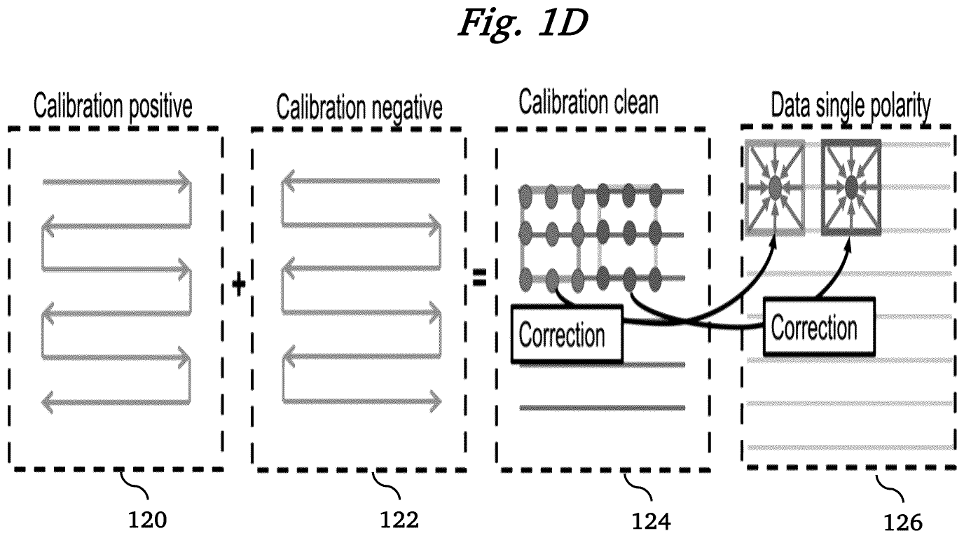

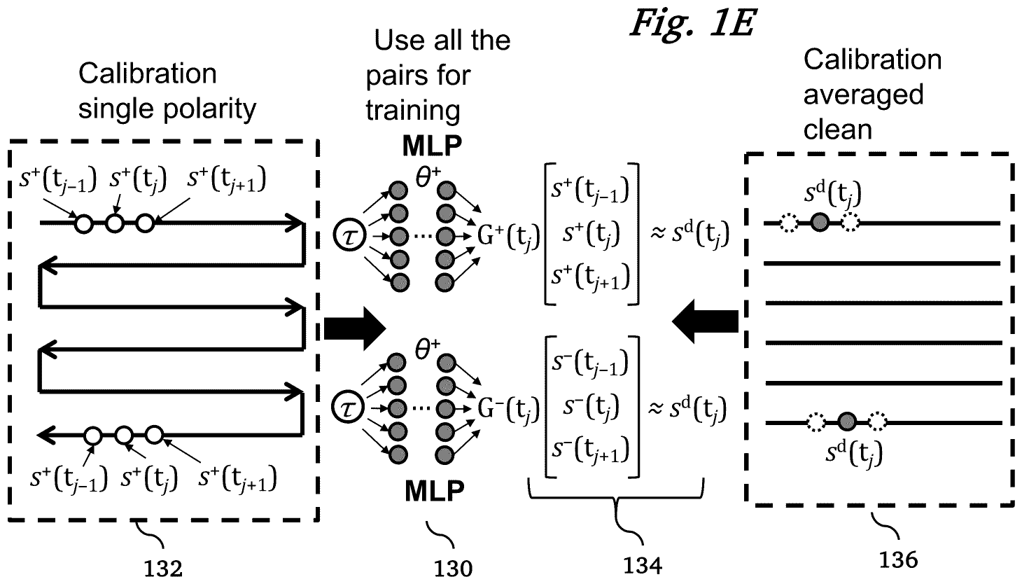

Existing methods for the correction of high-order odd-even phase differences include Skope measurement. Skope field probes (Skope, Switzerland) can be used to provide the gold-standard field measurement as:

$$S ( t ) = {\int }_{r} ρ ( r ) {e}^{i ( {C}_{0} ( t ) + {C}_{1} ( t ) r + {C}_{2} ( t ) {r}^{2} + {C}_{3} ( t ) {r}^{3} )} dr , \qquad ( 1 )$$

where S(t) is the k-space signal at time t, r is the spatial locations, Cⱼ(t) is the Skope-measured spherical harmonics coefficient at order j∈[0,3]. The 1st order coefficient C₁(t) is used as the trajectory for NUFFT reconstruction with ramp sampling. FIG. 1B shows a sampling path 100 and a Skope measurement error between the targeted and the actual field for both kx 102 and ky 104 coordinates.

Another existing method for correction of higher-order odd-even phase differences is dual polarity GRAPPA (DPG). DPG has been widely used in the actual EPI application. To estimate and correct the higher-order phase differences between odd and even echoes, DPG acquires the fully sampled low-resolution center k-space data in positive and negative polarity as the dual-polarity calibration data. The average of the dual-polarity calibration data provides clean calibration data. Two GRAPPA kernels are trained on the calibration data to correct the positive-polarity data and the negative-polarity data to clean data, respectively. During the actual data acquisition, the data is only acquired in a single polarity. The single-polarity data is first corrected with the dual-polarity kernel to remove the odd-even phase differences and then reconstructed with parallel imaging methods.

Another existing method is dual polarity average (DPA). DPG has demonstrated efficiency in numerous EPI applications. FIG. 1C illustrates dual polarity average (DPA) sampling, which samples EPI data at both polarity (positive 110 and negative 112), and averages them for “clean” outcome 114. However, when employing a high slew rate and a large portion of ramp sampling, the higher-order odd-even phase differences can be spatially and temporally varying. In such cases, the data with DPG correction may still present odd-even artifacts. To compensate for the spatiotemporally-varying odd-even phase differences, the data can be directly acquired in dual polarity. The complex average of the data cancels off most of the residual higher-order artifacts. DPA can serve as a reference for the clean data even with a high slew rate and ramp sampling. Nonetheless, it requires twice the scan time to acquire the data for both polarities.

The present inventors have developed techniques to address the high-order odd-even phase differences.

### Multi-Kernel DPG

To compensate for the field perturbation induced odd-even phase differences that spatially vary along readout due to ramp sampling, we developed a multi-kernel DPG technique. FIG. 1D illustrates dual-polarity GRAPPA (DPG) and multi-kernel DPG. It acquires the calibration data in both positive polarity 120 and negative polarity 122, then averages them for “clean” calibration 124, which is used to correct the single-polarity actual data 126. It trains multiple pairs of kernels for the correction of the odd and even data at different kₓ locations. It divides the calibration data into several blocks along kₓ. For each block, two kernels are trained to correct the positive and negative polarity as demonstrated in regular DPG. The actual single-polarity data is divided into the same blocks along kₓ, and each pair of kernels is used to correct a corresponding data block.

Multi-kernel DPG can effectively reduce the artifacts from spatially varying imperfections. However, it can potentially lead to increased noise levels due to the reduced amount of training data for each pair of kernels compared to regular DPG.

### Field-Correcting GRAPPA (FCG)

Although the field imperfection and induced odd-even phase differences along kₓ locations are varying, they are also highly correlated due to the low-varying nature of such imperfections. As such, the kernels along kₓ are highly correlated as well. To utilize the high correlation of kernels, instead of separately training multiple pairs of kernels, a network-based kernel is used to provide a compact representation of the spatial-varying information with limited data. As a demonstration, Multi-layer Perceptron (MLP) was used for the kernel representation. FIG. 1E illustrates FCG, which trains an MLP network 130 to take single-polarity data 132 and output dual-polarity “clean” data 134. The MLP is trained with averaged clean calibration data 136.

The input for MLP 130 is 3 to 5 data points from adjacent kₓ points from a single polarity 132 and the output is the clean center kₓ. The training of MLP 130 is performed as

$$arg {min}_{θ} {\sum }_{j} ‖ G ( {s}^{+} ( {t}_{j - 1} ) , {s}^{+} ( {t}_{j} ) , {s}^{+} ( {t}_{j + 1} ) , θ ) - {s}^{d} ( {t}_{j} ) ‖ , \qquad ( 3 )$$

where G is the MLP kernel with trainable parameter θ, s⁺(tⱼ) is the j-th signal acquired with positive polarity, s^{d}(tⱼ) is the dual polarity “clean” output. The MLP kernel pair is trained for both positive and negative polarity, respectively. In the actual acquisition, same as the DPG process, the corrupted single-polarity data was corrected with MLP kernel pair first to remove the odd-even phase differences, and then reconstructed with parallel imaging methods.

### Calibration Data Acquisition

A core idea for calibration data acquisition is to acquire paired source and target data. The source data is field-imperfection-corrupted, and the target data is artifact-free clean data. There are many ways to acquire such pairs. For example, a field camera can be used to acquire the phase variation during data acquisition to provide the clean data from the corrupted data. In this work, we used dual-polarity acquisition. The calibration data were acquired in both polarities. The single-polarity data forms the field-imperfection-corrupted source data. The average of the dual-polarity data forms the clean target data.

### Calibration Data Acquisition and Kernel Training for SMS-EPI

The correction for SMS-EPI faces extra challenges. Slices at different locations can have different linear components of the phase errors, requiring different linear corrections. We provided an example for acquiring paired corrupted and clean calibration data for SMS-EPI. We acquire the calibration data in a slice-by-slice manner covering all the slice locations. The input 120 or 132 is the synthetic eddy-current-corrupted SMS data as a direct collapse of raw slice-by-slice data. To obtain ghost-free target data 124 or 134, the raw slice-by-slice calibration data are first corrected with optimal linear ghost correction per slice, averaged over dual polarities for ghost-free slice-by-slice data, and finally collapsed to synthesize the ghost-free SMS data. The kernel is then trained and applied in the same way as illustrated in previous paragraphs.

### Experiments

The multi-kernel DPG and FCG methods were evaluated on phantoms and in vivo experiments at multiple systems to demonstrate the feasibility.

### Phantom and In Vivo Study on GE UHP System

The phantom study was first performed on a 3T GE clinical scanner (UHP, GE Healthcare) with a 32-channel head-coil (Nova Medical Inc). A 2D gradient echo sequence with EPI sampling was used, where the EPI trajectory is R=4, and all 4 shots were acquired in dual polarity. FIG. 1A illustrates the EPI trajectory with R4 design and 4 shot, full-ramp sampling. The maximum gradient and slew rate are 40 mT/m and 120 mT/m/ms. The EPI sampling parameters are: FOV=220×220 mm², spatial-resolution=1.1×1.1 mm², slice-thickness=2 mm, TE=25 ms, TR=2000 ms, flip-angle=90, echo-spacing=1.0 ms with 70% ramp sampling. The data were reconstructed using Skope measurement, DPG, DPA, multi-kernel DPG, and FCG, and the results were compared with DPA result as the reference.

An in vivo study was performed on the same system with the same sequence parameters.

### EPI and SMS-EPI Experiments on GE Magnus System

To test the performance of multi-kernel GRE and FCG under the condition of ultra-high gradient and slew rate, in vivo experiments were conducted on a high-performance 3T head-only system (SIGNA™ MAGNUS, GE Healthcare, Milwaukee, USA), whose maximum gradient amplitude and slew rate are 300 mT/m and 750 T/m/s. GRE sequences was used. The EPI trajectory was designed with following parameters: FOV=240×240 mm², in-plane resolution=1.0 mm², R=2, gmax=50 mT/m, smax=600 T/m/s, ESP=0.58 ms, ramp sampling factor=29%. Two experiments were performed: (1) slice-by-slice EPI; (2) SMS EPI with SMS=2 and 4-cm separation. The imaging data were corrected with DPA, DPG, mk-DPG, and FCG. After either correction, in-plane GRAPPA or slice-GRAPPA reconstruction was performed for parallel imaging.

### In Vivo Study on Siemens 7T System

To further test the performance of multi-kernel GRE and FCG at high-field systems, an in-vivo experiment was conducted on a 7T head-only system (Impulse, Siemens Healthineers, Germany). The product GRE-EPI sequence was used with following parameters: FOV=216×216 mm², in-plane resolution=0.8 mm², R=4, gmax=55 mT/m, smax=750 T/m/s, ESP=0.60 ms. The data were reconstructed using DPG, DPA, multi-kernel DPG, and FCG, and the results were compared with the DPA result as the reference.

### Results

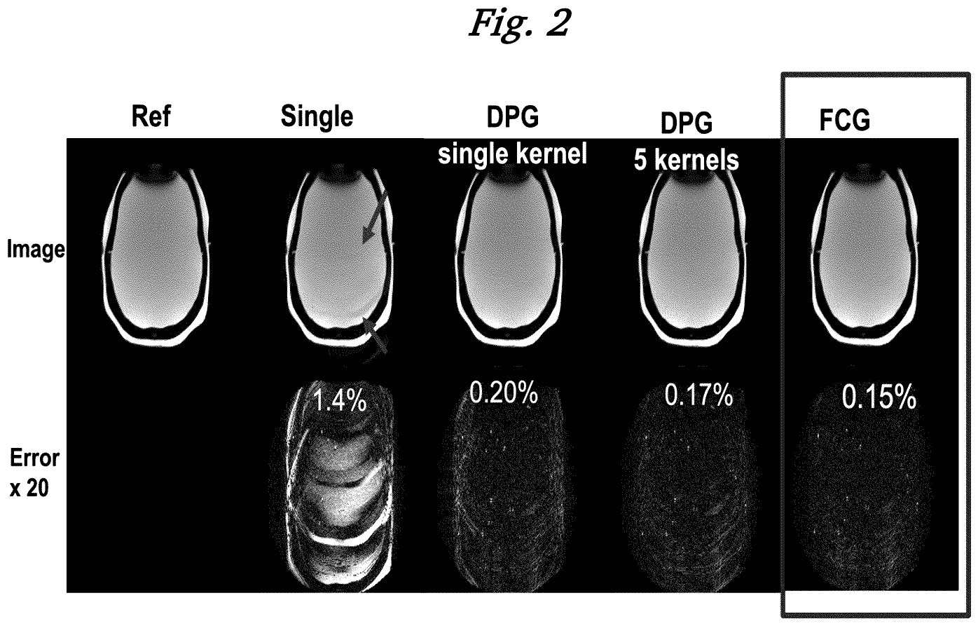

FIG. 2 shows phantom results on 3T UHP system with ramp sampling EPI trajectory as in FIG. 1A. The top row of images show (left to right) Ref, Single, DPG single kernel, multi-kernel DPG with 5 kernels (optimal), and FCG. The bottom row shows corresponding ×20 error images. The Ref data is the DPA data and all the error maps are generated by comparing with the Ref. Without any correction, the single average data showed visible artifacts and highest relative root mean square error. MLP produced the lowest error. DPG with 5 kernels showed similar output as MLP. DPA data is the reference. Single polarity reconstruction produced very strong artifacts, while DPG, multi-kernel DPG, and FCG can all largely reduce the artifacts and improve image quality, with FCG resulting in the lowest error. Multi-kernel DPG with 5 kernels produced better results over DPG and is close to the FCG performance.

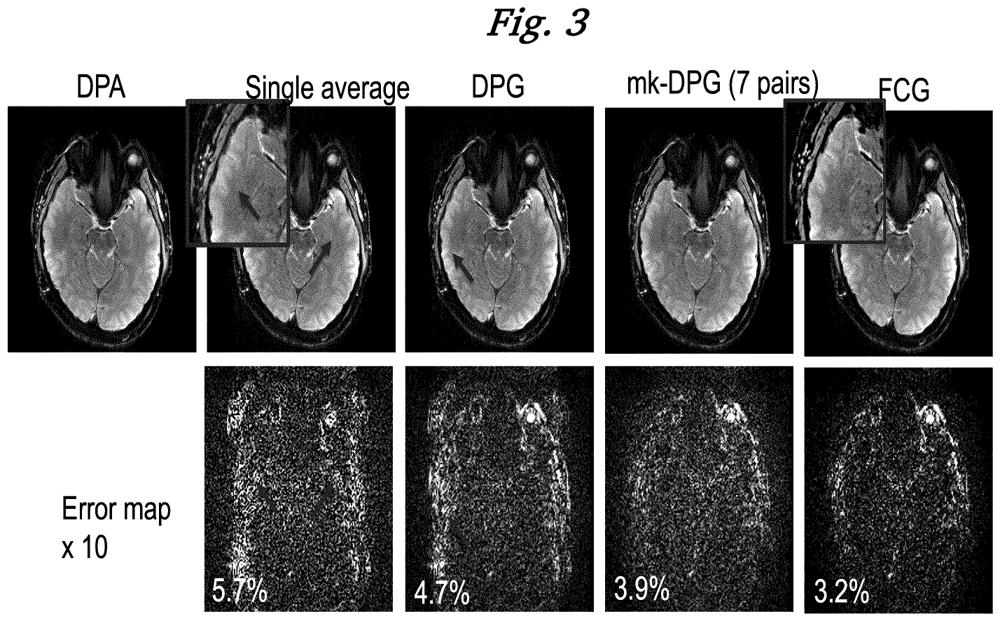

The slice-by-slice EPI study on 3T Magnus head-only ultra-high gradient system in FIG. 3. From left to right there are Ref, Single-polarity, DPG single kernel, multi-kernel DPG with 5 kernels (optimal), and FCG. The top row shows the images and the bottom row shows corresponding ×10 error images. These in vivo results are consistent with the previous phantom results, where multi-kernel DPG and FCG both show improved performance compared to the existing DPG technique. FCG produced the best correction.

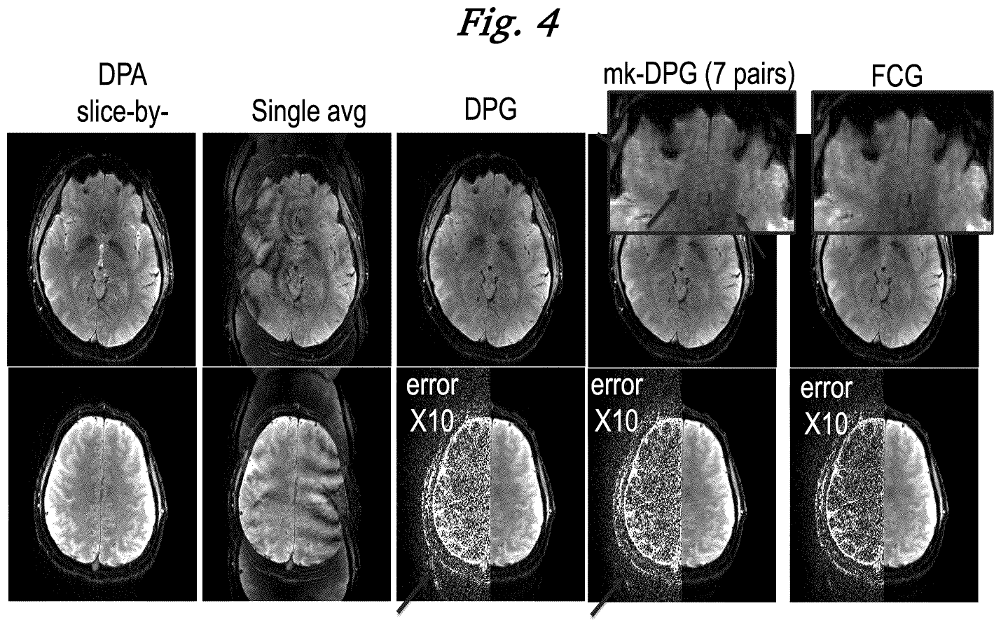

The SMS-EPI study on 3 T Magnus head-only ultra-high gradient system in FIG. 4 illustrates the same observations. The images show (left to right) Ref, Single, DPG, multi-kernel DPG with 7 kernels (optimal), and FCG. The top and bottom row shows slice 1 and slice 2 in SMS acquisition, respectively. Multi-kernel DPG and FCG provided improved image quality and reduced ghosting compared to DPG, with FCG showing the best performance and lowest noise.

### CONCLUSION

The generalized multi-kernel GRAPPA approaches demonstrated substantial improvement in reducing ghosting artifacts for different EPI applications. Among the approaches, FCG demonstrated the best image quality and lowest error in correcting field imperfection induced image artifacts. It has great potential to resolve the long-standing issue of EPI and can be extremely important for studies such as fMRI.

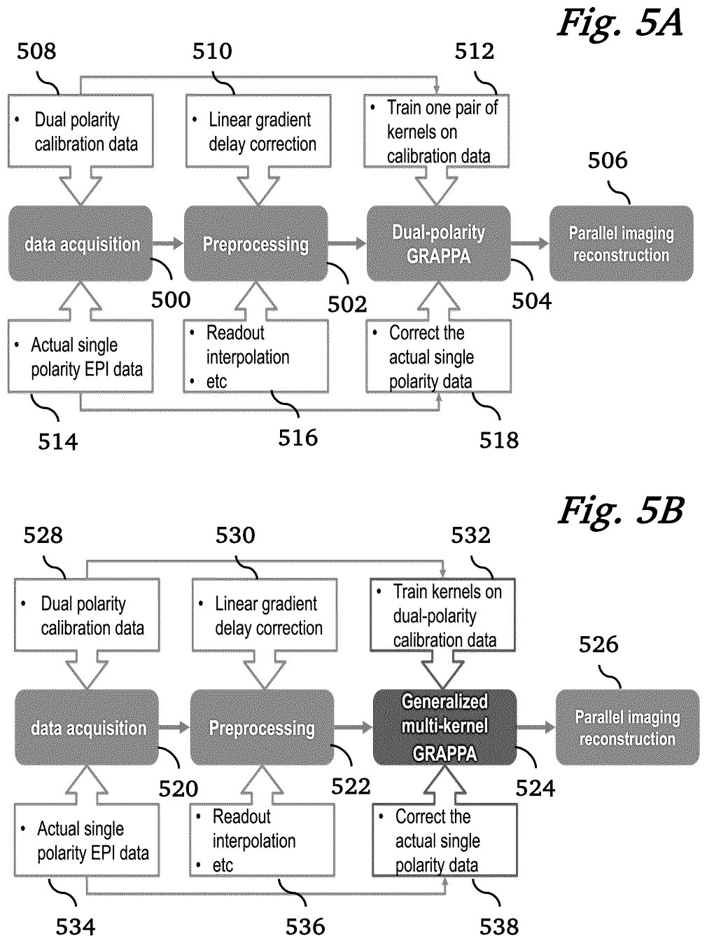

FIG. 5A is a flow chart outlining the standard EPI online reconstruction, and FIG. 5B is a flow chart outlining the generalized multi-kernel GRAPPA in an EPI scan according to an embodiment of the invention.

In FIG. 5A steps 500, 502, 504, 506 represent the main steps in the standard MRI scan pipeline. Standard dual-polarity calibration data 508 and actual single-polarity EPI data 514 are acquired during data acquisition 500, followed by the standardized preprocessing 502 including mainly the readout interpolation to Cartesian grids 516 and first-order gradient delay correction 510. The dual-polarity GRAPPA 504 is then performed, involving training 512 one pair of kernels on calibration data and correcting 518 the actual single polarity data. The process concludes with parallel imaging reconstruction 506.

In FIG. 5B the initial steps are similar. Dual-polarity calibration data 528 and actual single-polarity EPI data 534 are acquired during data acquisition 520, followed by the standardized preprocessing 522 including mainly the readout interpolation to Cartesian grids 536 and first-order gradient delay correction 530. Next, a key component of this method, the generalized multi-kernel GRAPPA 524 is performed, which replaces the dual-polarity GRAPPA 504 in the standard pipeline. The generalized multi-kernel GRAPPA 524 approach trains 532 multiple network-based kernels from the dual-polarity calibration data to correct 538 the spatial-varying field imperfection and applies them to all single-polarity EPI data. After the correction, the corrected single-polarity EPI data is reconstructed with standard parallel imaging reconstruction algorithms 526 (e.g., SENSE, GRAPPA, slice-GRAPPA).

1. A method for magnetic resonance imaging (MRI) comprising:
performing with an MRI scanner, an MRI data acquisition to acquire MRI data including calibration data for kernel training and regular EPI data having single polarity;
performing preprocessing of the MRI data including performing readout interpolation to Cartesian grids and first-order gradient delay correction;
performing a generalized multi-kernel GRAPPA using network-based kernels trained from the calibration data to correct spatial-varying field imperfections;
applying the network-based kernels to the regular EPI data to obtain clean data; and
reconstructing corrected single-polarity EPI data from the clean data using a parallel imaging reconstruction algorithm.

2. The method of claim 1 further comprising generating clean reference data from an average of the calibration data.

3. The method of claim 1 further comprising training the network-based kernels to map single-polarity corrupted data to dual-polarity averaged clean data.

4. The method of claim 1 further comprising applying the network-based kernels to acquired single-polarity corrupted data to produce clean data, and using the clean data for reconstruction of clean images.

5. The method of claim 1 further comprising training a multi-layer perceptron-based kernel to map adjacent k-space points in single-polarity corrupted calibration data to a center data point of corresponding spatial locations from dual-polarity-averaged clean calibration data.
